(19) United States
(12) Patent Application Publication
(10) Pub. No.: US 2026/0003005 A1
(43) Pub. Date: Jan. 1, 2026

(54) BATTERY STATE DIAGNOSIS APPARATUS AND METHOD THEREOF

(71) Applicants: HYUNDAI MOTOR COMPANY, SEOUL (KR); KIA CORPORATION, SEOUL (KR)

(72) Inventors: Cheol Beom Lim, Hwaseong-si (KR); Jin Woo Park, Hwaseong-si (KR); Yoon Sung Choi, Hwaseong-si (KR)

(73) Assignees: HYUNDAI MOTOR COMPANY, SEOUL (KR); KIA CORPORATION, SEOUL (KR)

(21) Appl. No.: 18/929,906

(22) Filed: Oct. 29, 2024

(30) Foreign Application Priority Data
Jun. 28, 2024 (KR) 10-2024-0085688

(51) Int. Cl. G01R 31/389; G01R 31/3842

(52) U.S. Cl. CPC G01R 31/389; G01R 31/3842

(57) ABSTRACT

A battery state diagnosis apparatus includes a processor configured to extract battery impedance by obtaining voltage and current signals outputted from a battery management system of an electric vehicle, removing noise by performing first signal processing on the voltage and current signals outputted from the battery management system, and extracting a frequency characteristic by performing second signal processing on the voltage and current signals from which the noise has been removed, and a storage configured to store data and algorithms driven by the processor.

### CROSS REFERENCE TO RELATED APPLICATIONS

This application claims priority to and the benefit of Korean Patent Application No. 10-2024-00085688, filed in the Korean Intellectual Property Office on Jun. 28, 2024, the entire contents of which are incorporated herein by reference.

### BACKGROUND

### (a) Field

The present disclosure relates to a battery state diagnosis apparatus and a method thereof, and more particularly, to a technique for extracting impedance of a battery in real time.

### (b) Description of the Related Art

Lithium ion batteries are currently widely used in various fields, particularly in electric vehicles. Accordingly, it is important to secure reliability of the batteries, and in response to a battery defect, to quickly identify and resolve it.

However, defects that occur inside the batteries are difficult to detect before disassembling the batteries.

Accordingly, in the past, battery impedance information was extracted by applying portable electrochemical impedance spectroscopy (EIS) equipment or an onboard EIS module.

In the case of portable EIS equipment, data reproducibility problems such as changes in contact resistance exist due to a user having to manually measure the data, and real-time measurements required for vehicle control application are difficult.

In the case of an electric vehicle battery EIS measurement device through the application of an on-board EIS module, a separate module is additionally required to process and synthesize the EIS data measured from each IC by applying a single cell supervisor (SCS) IC for individual cell EIS measurement to each unit, and an alternating current (AC) generator is additionally required, which requires additional cost and installation space.

### SUMMARY

An exemplary embodiment of the present disclosure attempts to provide a battery state diagnosis apparatus and a method thereof, capable of diagnosing a battery state by deriving battery impedance information in real time by applying signal processing technology using output information of a battery management system without separate electrochemical impedance spectroscopy (EIS) equipment.

An exemplary embodiment of the present disclosure attempts to provide a battery state diagnosis apparatus and a method thereof, capable of minimizing space and cost consumption by deriving battery impedance information using discrete wavelet transform (DWT) and short-time Fourier transform (STFT).

The technical objects of the present disclosure are not limited to the objects mentioned above, and other technical objects not mentioned may be clearly understood by those skilled in the art from the description of the claims.

An exemplary embodiment of the present disclosure provides a battery state diagnosis apparatus including: a processor configured to extract battery impedance by obtaining voltage and current signals outputted from a battery management system of an electric vehicle, removing noise performing first signal processing on the voltage and current signals outputted from the battery management system, and extracting a frequency characteristic performing second signal processing on the voltage and current signals from which the noise has been removed; and a storage configured to store data and algorithms driven by the processor.

In an exemplary embodiment of the present disclosure, the first signal processing may include a discrete wavelet transform (DWT).

In an exemplary embodiment of the present disclosure, the second signal processing may include a short-time Fourier transform (STFT).

In an exemplary embodiment of the present disclosure, signals outputted from the battery management system may include voltage and current signals.

In an exemplary embodiment of the present disclosure, the processor may be configured, during the first signal processing, to decompose each of the voltage and current signals outputted from the battery management system into high-frequency and low-frequency components according to at least one decomposition level (n).

In an exemplary embodiment of the present disclosure, the processor may be configured to derive a decomposition coefficient by taking convolution of each of the voltage and the current signals outputted from the battery management system and a wavelet function.

In an exemplary embodiment of the present disclosure, the processor may be configured to derive an approximation coefficient by taking convolution of the low-frequency component with a scaling function for low-frequency convolution, and to derive a detailed coefficient by taking convolution of the low-frequency component with a wavelet function for high-frequency convolution.

In an exemplary embodiment of the present disclosure, the processor may be configured to derive a decomposition coefficient including the detailed coefficient and the approximate coefficient.

In an exemplary embodiment of the present disclosure, the processor may be configured to remove noise by determining whether the decomposition coefficient is equal to or smaller than a predetermined threshold.

In an exemplary embodiment of the present disclosure, the processor may be configured to convert time-series-based voltage and current signals from which noise has been removed by performing the first signal processing into frequency-based voltage and current signals by performing the second signal processing.

In an exemplary embodiment of the present disclosure, the processor may be configured to extract frequency-based voltage and current signals by dividing the time-series-based voltage and current signals from which noise has been removed by performing the first signal processing into a plurality of segments based on time series and performing the second signal processing.

In an exemplary embodiment of the present disclosure, to perform the second signal processing for each of the segments by applying a predetermined overlap.

In an exemplary embodiment of the present disclosure, the processor may be configured to extract the battery impedance by applying Ohm's law to the frequency-based voltage and current signals.

In an exemplary embodiment of the present disclosure, the processor may be configured to separate and extract imaginary and real parts of the battery impedance.

In an exemplary embodiment of the present disclosure, the processor may be configured to diagnose a battery state using the battery impedance.

An exemplary embodiment of the present disclosure provides a battery state diagnosis method including obtaining, by a processor, voltage and current signals outputted from a battery management system of an electric vehicle, removing, by the processor, noise by performing first signal processing on the voltage and current signals outputted from the battery management system, extracting, by the processor, a frequency characteristic by performing second signal processing on the voltage and current signals from which the noise has been removed, and extracting, by the processor, battery impedance using the frequency characteristic.

In an exemplary embodiment of the present disclosure, the first signal processing may include a discrete wavelet transform (DWT), and the second signal processing may include a short-time Fourier transform (STFT).

In an exemplary embodiment of the present disclosure, the removing of the noise by performing the first signal processing may include: decomposing, by the processor, each of the voltage and current signals outputted from the battery management system into high-frequency and low-frequency components according to at least one decomposition level (n); deriving, by the processor, a decomposition coefficient by taking convolution of each of the voltage and the current signals outputted from the battery management system and a wavelet function; and removing, by the processor, noise by determining whether the decomposition coefficient is equal to or smaller than a predetermined threshold.

In an exemplary embodiment of the present disclosure, the extracting of the frequency characteristic by performing the second signal processing may include converting, by the processor, time-series-based voltage and current signals from which noise has been removed by performing the first signal processing into frequency-based voltage and current signals by performing the second signal processing.

In an exemplary embodiment of the present disclosure, the extracting of the frequency characteristic by performing the second signal processing may include extracting, by the processor, frequency-based voltage and current signals by dividing the time-series-based voltage and current signals from which noise has been removed by performing the first signal processing into a plurality of segments based on time series and performing the second signal processing.

In some embodiments, the extracting of the frequency characteristic by performing the second signal processing includes performing, by the processor, the second signal processing for each of the segments by applying a predetermined overlap, and extracting, by the processor, the battery impedance by applying Ohm's law to the frequency-based voltage and current signals.

According to the present technique, it may be possible to diagnose a battery state by deriving battery impedance information in real time by using signal processing technology based on output information of a battery management system without separate electrochemical impedance spectroscopy (EIS) equipment.

According to the present technique, it may be possible to minimize space and cost consumption by deriving battery impedance information using a discrete wavelet transform (DWT) and a short-time Fourier transform (STFT).

Furthermore, various effects which may be directly or indirectly identified through the present specification may be provided.

### BRIEF DESCRIPTION OF THE FIGURES

FIG. 1 illustrates a configuration of an example vehicle system including a battery state diagnosis apparatus.

FIG. 2 illustrates a flowchart showing an example battery state diagnosis method.

FIG. 3 illustrates a view for describing an example operating method of a discrete wavelet transform (DWT).

FIG. 4A and FIG. 4B each illustrate an example of signal waveforms of values D4 and D5 filtered by a high-pass filter in FIG. 3.

FIG. 4C illustrates an example decomposition coefficient and an example frequency domain for each decomposition level in FIG. 3.

FIGS. 5A, 5B, and FIG. 5C illustrate a view for describing an example process of applying a discrete wavelet transform (DWT) to a voltage signal.

FIGS. 5D, 5E, and FIG. 5F illustrate a view for describing an example process of applying a discrete wavelet transform (DWT) to a current signal.

FIGS. 6A, 6B, 6C, 6D, 6E, and FIG. 6F illustrate an example of noise removal according to a decomposition coefficient and a threshold value.

FIG. 7A and FIG. 7B illustrate views for describing example results of applying a short-time Fourier transform (STFT) to a voltage signal and a current signal.

FIG. 8A and FIG. 8B illustrate an example of STFT settings.

FIGS. 9A, 9B, 9C, and 9D to FIG. 9D illustrate an example of segment and overlap settings during a STFT.

FIGS. 10A, 10B, and FIG. 10C illustrates a view for describing an example impedance extraction process based on a STFT.

FIG. 11 illustrates an example of comparing results of battery impedance extraction based on signal processing and results of battery impedance extraction using EIS equipment.

FIG. 12 illustrates an example computing system.

### DETAILED DESCRIPTION

Hereinafter, some exemplary embodiments of the present disclosure will be described in detail with reference to exemplary drawings. It should be noted that in adding reference numerals to constituent elements of each drawing, the same constituent elements include the same reference numerals as possible even though they are indicated on different drawings. In describing an exemplary embodiment of the present disclosure, when it is determined that a detailed description of the well-known configuration or function associated with the exemplary embodiment of the present disclosure may obscure the gist of the present disclosure, it will be omitted.

In describing constituent elements according to an exemplary embodiment of the present disclosure, terms such as first, second, A, B, (a), and (b) may be used. These terms are only for distinguishing the constituent elements from other constituent elements, and the nature, sequences, or orders of the constituent elements are not limited by the terms. Furthermore, all terms used herein including technical scientific terms have the same meanings as those which are generally understood by those skilled in the technical field to which an exemplary embodiment of the present disclosure pertains (those skilled in the art) unless they are differently defined. Terms defined in a generally used dictionary shall be construed to have meanings matching those in the context of a related art, and shall not be construed to have idealized or excessively formal meanings unless they are clearly defined in the present specification.

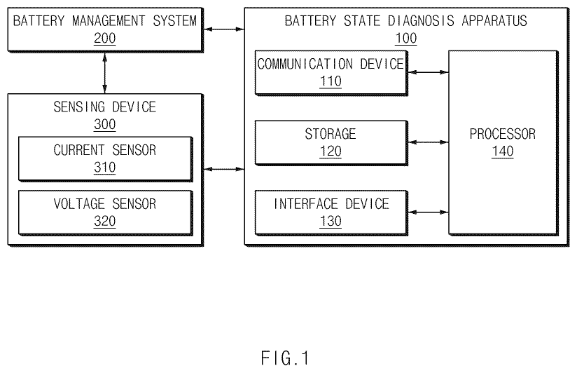

Hereinafter, various exemplary embodiments of the present disclosure will be described in detail with reference to FIG. 1 to FIG. 12.

FIG. 1 illustrates a configuration of an example vehicle system including a battery state diagnosis apparatus.

Referring to FIG. 1, a vehicle system according to an embodiment of the present disclosure may include a battery state diagnosis apparatus 100, a battery management system 100, and a sensing device 300.

The battery status diagnosis apparatus 100 may be configured to diagnose a battery state by extracting impedance of a battery in a vehicle using a signal from the battery management system 200 of the vehicle using the battery.

The battery management system 200 is a battery management system (BMS), and may manage the battery state.

The sensing device 300 may detect a voltage signal and a current signal outputted from the battery management system 200 to supply the detected voltage signal and current signal to the battery state diagnosis apparatus 100. To this end, the sensing device 300 may include a current sensor 310, a voltage sensor 320, etc.

The battery state diagnosis apparatus 100 according to the present disclosure may be implemented inside or outside the vehicle. In the instant case, the battery state diagnosis apparatus 100 may be integrally formed with internal control units of the vehicle, or may be implemented as a separate hardware device to be connected to control units of the vehicle by a connection means. For example, the battery state diagnosis apparatus 100 may be implemented integrally with the vehicle, may be implemented in a form that is installed or attached to the vehicle as a configuration separate from the vehicle, or a part thereof may be implemented integrally with the vehicle, and another part may be implemented in a form that is installed or attached to the vehicle as a configuration separate from the vehicle.

Referring to FIG. 1, the battery state diagnosis apparatus 100 may include a communication device 110, a storage 120, an interface device 130, and a processor 140. According to an exemplary embodiment of the present disclosure, the battery state diagnosis apparatus 100 may be implemented as a single body by coupling components with each other, and some components may be omitted.

The communication device 110 is a hardware device implemented with various electronic circuits to transmit and receive signals through a wireless or wired connection, and may transmit and receive information based on in-vehicle devices and in-vehicle network communication techniques. As an exemplary embodiment of the present disclosure, the in-vehicle network communication techniques may include Controller Area Network (CAN) communication, Local Interconnect Network (LIN) communication, flex-ray communication, and the like.

The storage 120 may store sensing results and the sensing device 300 and data and/or algorithms required for the processor 140 to operate, and the like.

For example, the storage 120 may store algorithms based on a discrete wavelet transform (DWT) and a short-time Fourier transform (STFT).

For example, the storage 120 may store a current value measured by the current sensor and a voltage value measured by the voltage sensor. The storage 120 may store predetermined setting information (e.g., reference value, etc.). To this end, the sensing device 300 may include a current sensor 310, a voltage sensor 320, etc.

The storage 120 may include a storage medium of at least one type among memories of types such as a flash memory, a hard disk, a micro, a card (e.g., a secure digital (SD) card or an extreme digital (XD) card), a random access memory (RAM), a static RAM (SRAM), a read-only memory (ROM), a programmable ROM (PROM), an electrically erasable PROM (EEPROM), a magnetic memory (MRAM), a magnetic disk, and an optical disk.

The processor 140 may be electrically connected to the communication device 110, the storage 120, the interface unit 130, etc., and configured to perform overall control such that each component may normally perform its function. Furthermore, the processor 140 may be an electrical circuit that may be configured to electrically control each component, and to execute a command of software, thereby performing various data processing and calculations to be described later.

The processor 140 may be implemented in the form of hardware, software, or a combination of and software. For example, the processor 140 may be implemented as a microprocessor, but the present disclosure is not limited thereto. For example, it may be, e.g., an electronic control unit (ECU), a micro controller unit (MCU), or other subcontrollers mounted in the vehicle.

The processor 140 may be implemented with an application specific integrated circuit (ASIC), a digital signal processor (DSP), a programmable logic device (PLD), a field programmable gate array (FPGA), a central processing unit (CPU), a microcontroller, a microprocessor and/or the like.

The processor 140 may be configured to obtain a signal outputted from the battery management system 200 of the electric vehicle, to perform a first signal processing on the signal outputted from the battery management system 200 to remove noise, and may configured to perform a second signal processing on the signal from which noise has been removed to extract frequency characteristics and to extract battery impedance.

In the instant case, the first signal processing may indicate a discrete wavelet transform (DWT), and the second signal processing may indicate a short-time Fourier transform (STFT).

The DWT and the STFT each are a type of Fourier transform, and the Fourier transform is a decomposition into basis functions including cosines and sines, and the discrete wavelet transform (DWT) is a discrete wavelet transform, which may indicate decomposing into basis functions of small waves called wavelets.

Furthermore, the Fourier transform may be difficult to identify changes in waves that are not sine waves (sine functions, cosine functions) but have sharp points, so shortcomings of the Fourier transform may be compensated for by dividing it into certain time blocks (windows) and applying the Fourier transform to each block, which is called the short-time Fourier transform (STFT).

Furthermore, signals outputted from the battery management system 200 may include voltage signals and current signals.

During the first signal processing, the processor 140 may be configured to decompose each of the voltage signals and current signals outputted from the battery management system 200 into a high-frequency component and a low-frequency component according to at least one decomposition level (n).

The processor 140 may be configured to derive a decomposition coefficient by taking convolution of each of the voltage and the current signals outputted from the battery management system 200 and a wavelet function.

The processor 140 may be configured to derive an approximation coefficient by taking convolution of a low-frequency component with a scaling function for low-frequency convolution, and to derive a detailed coefficient by taking convolution of a low-frequency component with a wavelet function for high-frequency convolution.

The processor 140 may be configured to derive a decomposition coefficient including a detailed coefficient and an approximate coefficient.

The processor 140 may be configured to remove noise by determining whether the decomposition coefficient is equal to or smaller than a predetermined threshold.

The processor 140 may be configured to convert time-series-based voltage and current signals from which noise has been removed by performing first signal processing into frequency-based voltage and current signals by performing second signal processing.

The processor 140 may be configured to extract frequency-based voltage and current signals by dividing the time-series-based voltage and current signals from which noise has been removed by performing the first signal processing into a plurality of segments based on the time series and performing the second signal processing.

The processor 140 may be configured to perform the second signal processing for each of the segments by applying a predetermined overlap.

The processor 140 may be configured to extract battery impedance by applying Ohm's law to the frequency-based voltage and current signals.

The processor 140 may be configured to separate and extract the imaginary and real parts of the battery impedance.

The processor 140 may be configured to diagnose the battery state using the battery impedance.

In this way, according to the present disclosure, by extracting the battery impedance of an electric vehicle based on a signal processing algorithm, the battery state may be diagnosed, thereby minimizing vehicle space and cost consumption.

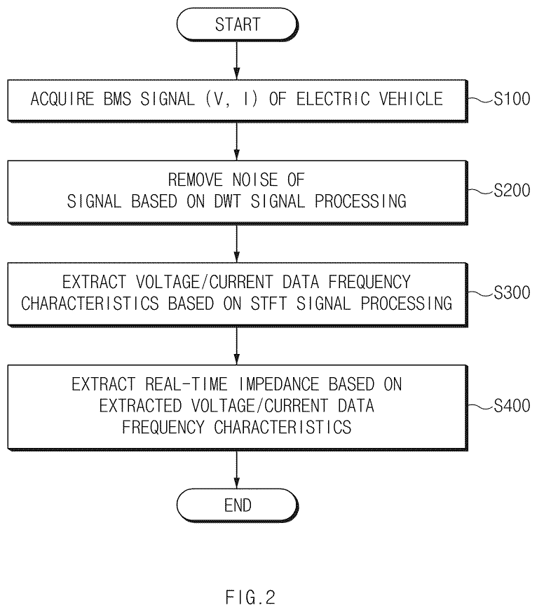

Hereinafter, a battery state diagnosis method according to an exemplary embodiment of the present disclosure will be described with reference to FIG. 2. FIG. 2 illustrates a flowchart showing an example battery state diagnosis method.

Hereinafter, it is assumed that the battery state diagnosis apparatus 100 of FIG. 1 performs processes of FIG. 2. Furthermore, in the description of FIG. 2, operations described as being performed by a device may be understood as being controlled by the processor 140 of the battery state diagnosis apparatus 100. In following exemplary embodiments, operations of steps S100 to S400 may be performed sequentially, but are not necessarily performed sequentially. For example, an order of each operation may be changed, and at least two operations may be performed in parallel.

Referring to FIG. 2, the battery condition diagnosis apparatus 100 may acquire current and voltage signals of the battery management system (BMS) 200 of the electric vehicle (S100). In the instant case, the battery condition diagnosis apparatus 100 may be configured to acquire the current and voltage signals of the battery management system (BMS) 200 through the current sensor 310 and the voltage sensor 320 of the sensing device 300.

The voltage and current signals acquired from the battery management system (BMS) 200 contain many noise components, and such noise may be removed to extract impedance with high reliability.

Accordingly, the battery state diagnosis apparatus 100 may be configured to remove noise by performing discrete wavelet transform (DWT) signal processing (S200). In the instant case, the battery condition diagnosis apparatus 100 may be configured to perform data decomposition of the acquired current and voltage signals for each frequency level, and may decompose voltage data and current data for each frequency level through the DWT. That is, the battery state diagnosis apparatus 100 may be configured to extract time domain data for each frequency through the DWT.

The battery state diagnosis apparatus 100 may be configured to extract voltage data frequency characteristics and current data frequency characteristics by performing short-time Fourier transform (STFT) signal processing based on the signals from which noise has been removed through DWT signal processing in the above operation S200 (S300). That is, the battery state diagnosis apparatus 100 may be configured to extract frequency characteristics by converting the characteristics of time domain data to the frequency domain in the operation S200.

It may be difficult to extract frequency characteristics in real time for a long period from voltage signals and current signals acquired from the battery management system (BMS) 200 of an actual vehicle, so in the present disclosure, the STFT may be applied to segment the voltage and current signals acquired from the battery management system (BMS) 200 of an actual vehicle into short units, so as to extract frequency characteristics of the voltage and current signals acquired from the battery management system (BMS) 200 of an actual vehicle in real time.

The battery state diagnosis apparatus 100 may be configured to extract real-time impedance based on the extracted voltage and current frequency characteristics (S400). That is, the battery state diagnosis apparatus 100 may be configured to extract real-time impedance for each frequency by applying Ohm's law.

The battery state diagnosis apparatus 100 may be configured to diagnose the battery state based on the extracted battery impedance information, and to transmit a battery state diagnosis result thereof to a control device (not shown) in the vehicle so as to reflect it in the vehicle control.

In this way, the battery state diagnosis apparatus 100 may be configured to remove noise from the voltage and current signals of the battery management system 200 through the DWT, and to extract a time domain signal by performing data decomposition for each frequency level, and then the to secure a raw signal for AC impedance extraction by extracting a DC-based time domain signal for each frequency through the STFT, and by applying Ohm's law, and to extract AC impedance for each frequency based on a frequency domain.

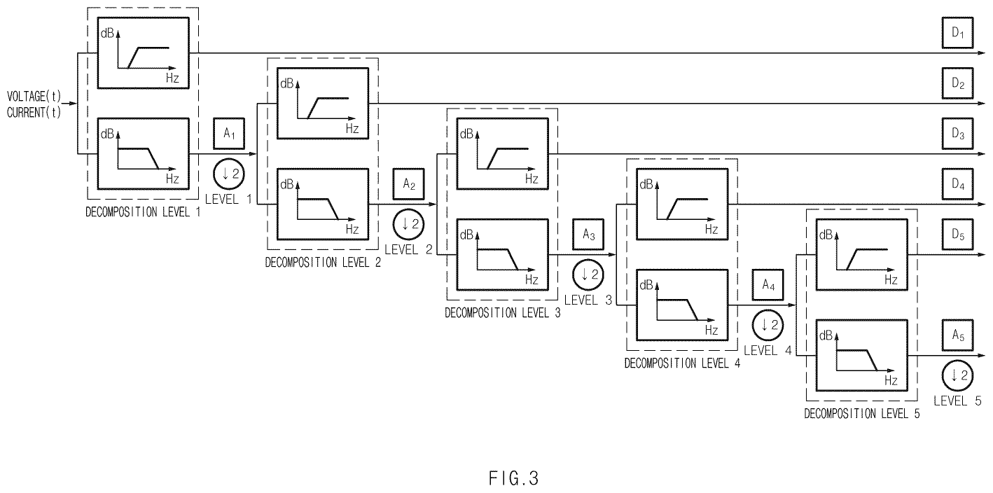

Hereinafter, the DWT signal processing will be described in detail with reference to FIGS. 3 to 5B.

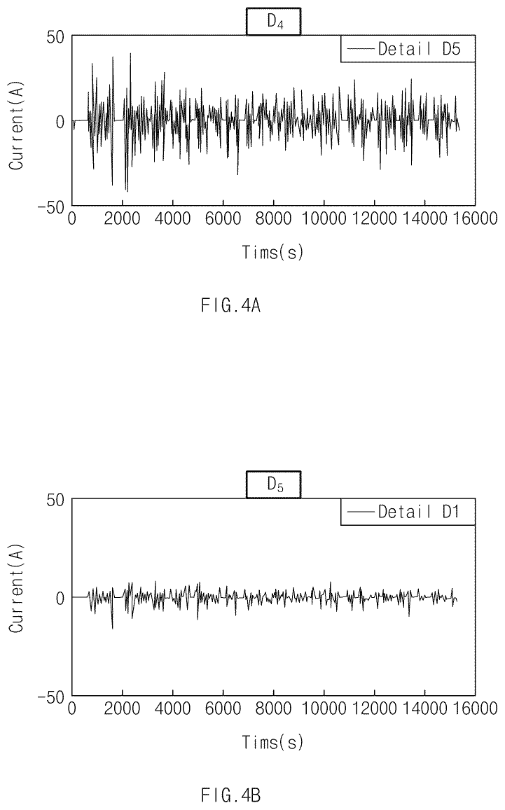

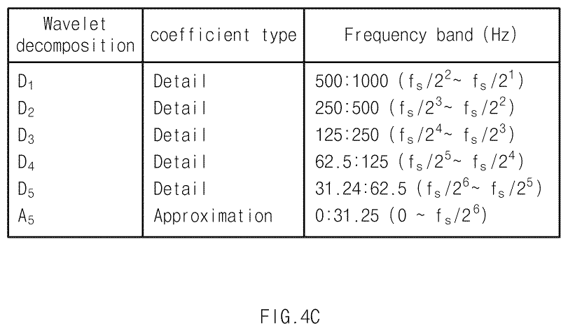

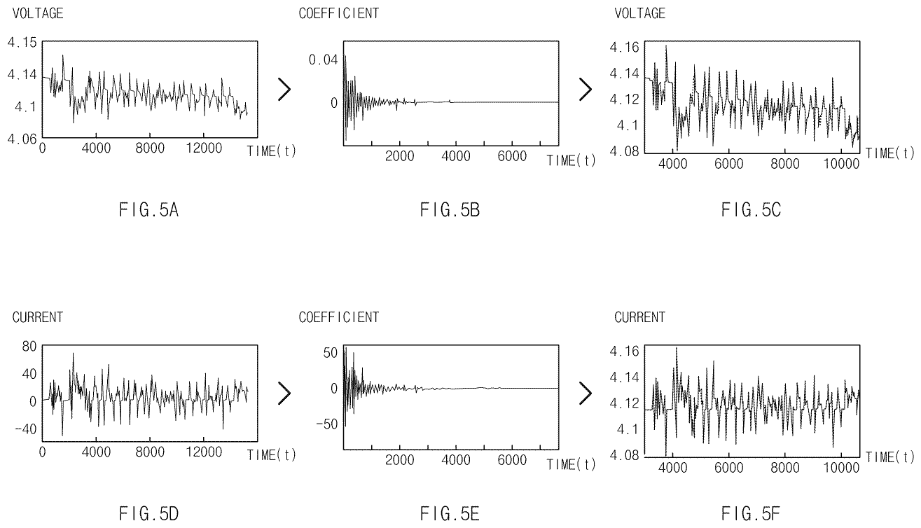

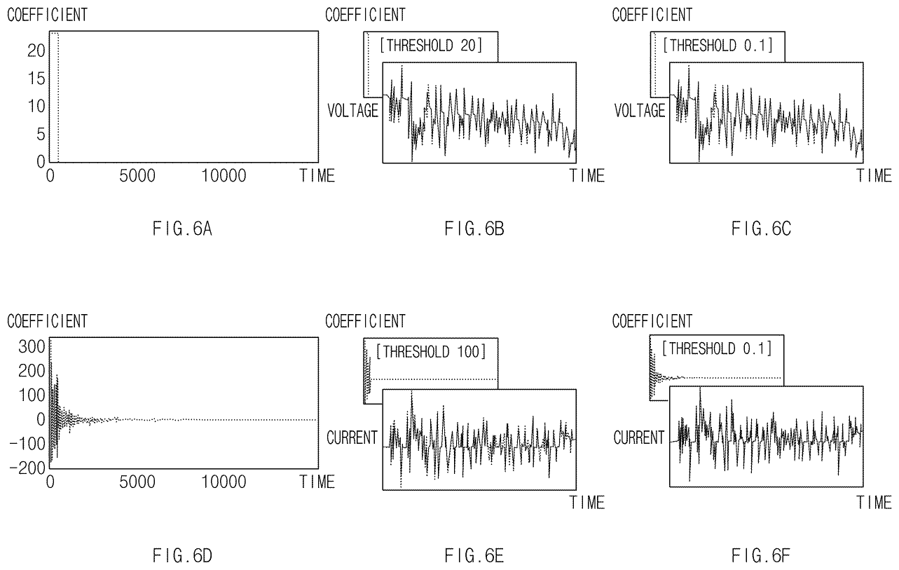

The battery state diagnosis apparatus 100 may be configured to decompose voltage and current signals of the battery management system 200 into high-frequency components and low-frequency components through a DWT to decompose data for each frequency level (FIGS. 3 to 4C). Then, the battery state diagnosis apparatus 100 may be configured to extract a decomposition coefficient using level-by-level decomposition data, and in response to a case where the decomposition coefficient is smaller than a threshold, may be configured to remove the corresponding signal as noise (FIG. 5A to FIG. 5F).

FIG. 3 illustrates a view for describing an example operating method of a discrete wavelet transform (DWT), and discloses an example in which the battery state diagnosis apparatus 100 decomposes voltage and current signals of the battery management system 200 into high frequency signals and low frequency signals, respectively.

Referring to FIG. 3, an example of decomposing a signal for each level through the DWT signal processing is disclosed. FIG. 3 shows an example including decomposition level 1, decomposition level 2, decomposition level 3, decomposition level 4, and decomposition level 5, but the present disclosure is not limited thereto, and a number of decomposition levels may be greater. Furthermore, a high-pass filtered signal outputted for each decomposition level is a Dn (Detail) signal, and a low-pass filtered signal is an An (Approximation) signal, where n may indicate each level. Furthermore, the battery state diagnosis apparatus 100 may be configured to perform filtering by reducing a sampling rate of the low-frequency signal and a sampling rate of the high-frequency signal by half for each decomposition level.

More specifically, at decomposition level 1, the battery state diagnosis apparatus 100 may perform first high-pass filtering (500 Hz to 1000 Hz) and first low-pass filtering (500 Hz to 1 Hz) on the current signal. In the instant case, a first high-frequency signal D1 may be extracted through the first high-pass filtering, and a first low-frequency signal A1 may be outputted through the first low-pass filtering.

Then, at decomposition level 2, the battery state diagnosis apparatus 100 may be configured to perform second high-pass filtering (250 Hz to 500 Hz) on the first low-frequency signal A₁ to extract a second high-frequency signal D₂, and to perform second low-pass filtering (250 Hz to 1 Hz) on the first low-frequency signal A₁ to output a second low-frequency signal A₂.

Then, at decomposition level 3, the battery state diagnosis apparatus 100 may be configured to perform third high-pass filtering (125 Hz to 250 Hz) on the second low-frequency signal A₂ to extract a third high-frequency signal D₃, and to perform third low-pass filtering (125 Hz to 1 Hz) on the second low-frequency signal A₂ to output a third low-frequency signal A₃.

Then, at decomposition level 4, the battery state diagnosis apparatus 100 may be configured to perform fourth high-pass filtering (62.5 Hz to 125 Hz) on the third low-frequency signal A₃ to extract the fourth high-frequency signal D₄, and to perform fourth low-pass filtering (62.5 Hz to 1 Hz) on the third low-frequency signal A₃ to output a fourth low-frequency signal A₄. FIG. 4A illustrates an example waveform of a fourth high frequency signal D₄.

Then, at decomposition level 5, the battery state diagnosis apparatus 100 may be configured to perform fifth high-pass filtering (31.25 Hz to 62.5 Hz) on the fourth low-frequency signal A₄ to extract the fifth high-frequency signal D₅, and to perform fifth low-pass filtering (31.25 Hz to 1 Hz) on the fourth low-frequency signal A₄ to output a fifth low-frequency signal A₅. FIG. 4B illustrates an example waveform of a fifth high frequency signal D₅.

The battery state diagnosis apparatus 100 may be configured to decompose into N high-frequency signals and N low-frequency signals by performing the level-by-level decomposition (decomposition level 1, decomposition level 2, decomposition level 3, decomposition level 4, decomposition level 5) of the above-described signal in the same way for the voltage signal.

In this way, the voltage and current signals acquired from the battery management system 200 may be formed of a high-frequency signal and a low-frequency signal, and the battery state diagnosis apparatus 100 may be configured to divide the frequency into 2ⁿ according to the decomposition level (n) and decompose it into a high-frequency component (high pass filter) and a low-frequency component (low pass filter).

FIG. 4C illustrates an example decomposition coefficient and an example frequency domain for each decomposition level in FIG. 3. That is, for example, a frequency of the voltage signal, which is 2000 Hz, may represent a resolution factor and a frequency band for each resolution level.

A coefficient type of the first high-frequency signal D₁ may be a high frequency (Detail), and a frequency band thereof may be 500 Hz to 1000 Hz. A coefficient type of the second high-frequency signal D₂ may be a high frequency (Detail), and a frequency band thereof may be 250 Hz to 500 Hz. A coefficient type of the third high-frequency signal D₃ may be a high frequency (Detail), and a frequency band thereof may be 125 Hz to 250 Hz. A coefficient type of the fourth high-frequency signal D₄ may be a high frequency (Detail), and a frequency band thereof may be 62.5 Hz to 125 Hz. A coefficient type of the fifth high-frequency signal D₅ may be a high frequency (Detail), and a frequency band thereof may be 31.25 Hz to 62.5 Hz.

A coefficient type of the first low-frequency signal A₁ may be a low frequency (Approximation), and a frequency band thereof may be 1 to 31.25 Hz.

The battery state diagnosis apparatus 100 may be configured to determine a decomposition level coefficient as shown in FIG. 5A to FIG. 5F by using decomposition level signals decomposed into high-frequency and low-frequency signals as shown in FIG. 3, and to remove noise from voltage and current signals of the battery management system 200 by comparing the decomposition level coefficient with a predetermined threshold.

FIG. 5A to FIG. 5C illustrate a view for describing an example process of removing noise by applying a discrete wavelet Transform (DWT) to a voltage signal measured from the battery management system 200, and FIG. 5D to FIG. 5F illustrate a view for describing an example process of removing noise by applying a discrete wavelet transform (DWT) to a current signal measured from the battery management system 200.

FIG. 5A shows an example of a voltage signal, which is a voltage signal acquired by the voltage sensor 320 from the battery management system 200, and FIG. 5D shows an example of a current signal, which is a current signal acquired by the current sensor 310 from the battery management system 200.

FIG. 5B shows an example of the battery state diagnosis apparatus 100 decomposing voltage signals into levels based on DWT signal processing and deriving a decomposition coefficient, and FIG. 5E shows an example of decomposing a current signal into levels based on the DWT signal processing and deriving a decomposition coefficient. The battery state diagnosis apparatus 100 may be configured to derive a coefficient according to a wavelet function and an arbitrarily set decomposition level.

The battery state diagnosis apparatus 100 may be configured to derive the decomposition coefficient (W) based on convolution of each of the voltage and current signals of the battery management system 200 and the wavelet function. That is, the battery state diagnosis apparatus 100 may be configured to derive the decomposition coefficient (W) of time series data based on a convolution of a time series signal x(t) and the wavelet function. In the instant case, the decomposition coefficient (W) may be generated to include approximation coefficients (a_{j,k}) and detailed coefficients (d_{j,k}) as in Equation 1 below.

$$W = 〈 {a}_{j , k} , {d}_{j , k} 〉 \qquad Equation 1$$

The approximation coefficient (a_{j,k}) and the detailed coefficient (d_{j,k}) may each be determined by taking convolution of a time series signal x(t) and a wavelet function φ(t), ψ(t) as in Equation 2 below. In the instant case, the time series signal x(t) may indicate each of the low-frequency component signals (A₁, A₂, A₃, A₄ . . . ) among the current original signal, voltage original signal, and level-decomposed signals,

$${a}_{j , k} = x ( t ) * φ ( t ) \qquad Equation 2$$

$${d}_{j , k} = x ( t ) * ψ ( t )$$

If Equation 1 and Equation 2 are expressed more specifically, the decomposition coefficient (W) may be derived as shown in Equation 3 below.

$$W ( {}^{*} j {,}^{*} k ) = \frac{1}{\sqrt{2 j}} {\int }_{- ∞}^{∞} x ( t ) ψ ( \frac{t - k 2 j}{2 j} ) d t \qquad Equation 3$$

In the instant case, j may indicate the compression coefficient that determines a magnitude thereof, and this compression coefficient may be set arbitrarily. k may indicate a transition coefficient related to movement on a time axis, and may be arbitrarily set. Furthermore, the wavelet function may be set to various magnitudes (levels).

$${\int }_{- ∞}^{∞} x ( t ) ψ ( \frac{t - k 2 j}{2 j} ) d t$$

may include two-time convolution (low-frequency component convolution, high-frequency component convolution) as in Equation 4 and Equation 5.

Equation 4 below may represent a wavelet function (scaling function) for convolution of a low-frequency signal, and Equation 5 may represent a wavelet function for convolution of a high-frequency signal. The approximation coefficient and the detailed coefficient may be respectively derived by applying the wavelet functions of Equations 4 and 5 to Equation 3, and the decomposition coefficient may be derived using the approximation coefficient and the detailed coefficients.

$$ϕ ( t ) = \sqrt{2} {\sum }_{k = - ∞}^{∞} {h}_{0} ( k ) ϕ ( 2 t - k ) \qquad Equation 4$$

$$Ψ ( t ) = \sqrt{2} {\sum }_{k = - ∞}^{∞} {h}_{1} ( k ) ϕ ( 2 t - k ) \qquad Equation 5$$

φ may indicate the scaling function, Ψ may indicate the wavelet function, h₀ may indicate the scaling function filter coefficient (low pass filter (LPF)), and

$$\frac{1}{\sqrt{2}}$$

may be [1,2,1] and may vary depending on the wavelet function. h₁ may indicate the wavelet function filter coefficient (high pass filter (HPF)),

$$\frac{1}{\sqrt{2}}$$

may be [−1,−2,1] anu may vary depending on the wavelet function. In h₀(k), k may indicate an index of the filter, and in (2t−k), k may indicate moving in time.

Referring to FIGS. 5B and 5E it may be seen that as the decomposition coefficient increases, it has a high correlation with the time series signal data, and as the decomposition coefficient decreases, it has a low correlation with the time series signal data. In the instant case, portions that have low correlation with time series signal data may be judged as noise, and to this end, the battery state diagnosis apparatus 100 may be configured to set a threshold in advance and adjust the coefficient to 0 to remove noise in response to a case where the decomposition coefficient is smaller than the predetermined threshold. That is, the battery state diagnosis apparatus 100 may be configured to remove noise by adjusting the frequency coefficient to 0 by determining that it is not a frequency component in response to a case where the resolution coefficient is equal to or smaller than the predetermined threshold.

FIG. 5C shows an example of removing noise from a voltage signal decomposed for each level based on the predetermined threshold, and FIG. 5F shows an example of removing noise from a current signal decomposed for each level based on the predetermined threshold.

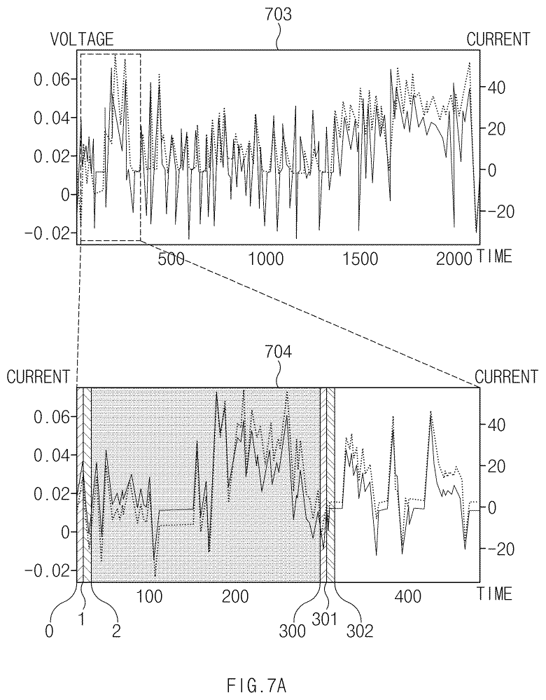

FIG. 6 illustrates an example of noise removal according to a decomposition coefficient and a threshold value.

Referring to FIG. 6, FIG. 6A shows a decomposition factor derived from a voltage signal, FIG. 6B shows a decomposition factor derived from a current signal, FIG. 6C shows an example where noise is removed in response to a case where the decomposition factor of the voltage signal of FIG. 6A is smaller than or equal to 20 because the threshold is 20, and FIG. 6D shows an example where noise is removed in response to a case where the decomposition factor of the voltage signal of FIG. 6A is smaller than or equal to 0.1 because the threshold is 0.1.

FIG. 6E shows an example where noise is removed in response to a case where the decomposition factor of the current signal of FIG. 6B is smaller than or equal to 100 because the threshold is 100, and FIG. 6F shows an example where noise is removed in response to a case where the decomposition factor of the current signal of FIG. 6B is smaller than or equal to 0.1 because the threshold is 0.1.

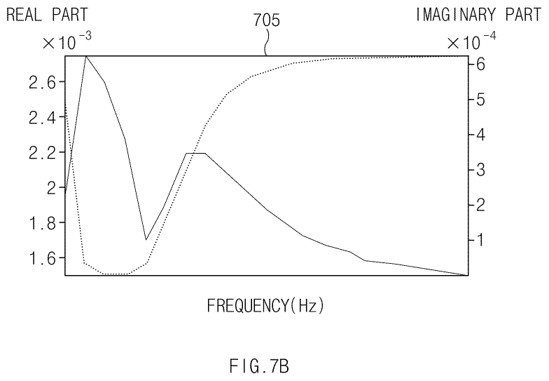

Hereinafter, STFT signal processing will be described in detail with reference to FIGS. 7A to 10.

FIG. 7A and FIG. 7B illustrate views for describing example results of applying a short-time Fourier transform (STFT) to a voltage signal and a current signal.

In the case of voltage and current signals of the battery management system 200 of an actual electric vehicle, it is difficult to perform periodic extraction for each frequency for a long period of time in real time, so in the present disclosure, STFT signal processing may be applied to segment the segments into short time units, so as to derive real-time frequency characteristics for each segment.

The battery state diagnosis apparatus 100 may be configured to set segment and overlap for each of the voltage and current signals to which noise has been removed by applying the DWT. In the instant case, the segment and the overlap may be arbitrarily set by a user, and may be set by deriving an optimal value based on experimental values. In the instant case, the segment indicates an STFT parameter and indicates a frequency conversion limit for all the time series data, meaning a magnitude arbitrarily set for frequency conversion for each time domain. Furthermore, the overlaps are moved in parallel as an overlapping interval.

In FIG. 7A, for example, the segment is set to “300” and the overlap is set to “1”, and for convenience of description, each segment portion is enlarged and illustrated.

That is, STFT is performed on 0-300s segment of the voltage signal, then shifted by 1, STFT is performed on 1-301s segment, and then shifted by 1, STFT is performed on 2-302s segment.

In this way, according to the present disclosure, it may be possible to perform periodic extraction for each frequency of a long time term by performing STFT by overlapping.

The battery state diagnosis apparatus 100 may be configured to extract segment-based frequency components for each set overlap of the voltage and current signals from which noise has been removed through DWT processing.

That is, frequency characteristics derived by performing the STFT for each segment on the voltage and current signals as in FIG. 7A may be expressed as in FIG. 7B. That is, the battery state diagnosis apparatus 100 may be configured to extract impedance by applying the frequency component of each voltage segment and the frequency component of each current segment to Ohm's law in Equation 6 below.

$$Z ( f ) = \frac{V ( f )}{I ( f )} \qquad Equation 6$$

Impedance (Z) may include a real part and an imaginary part, and the real part and the imaginary part may be extracted separately as shown in FIG. 7B.

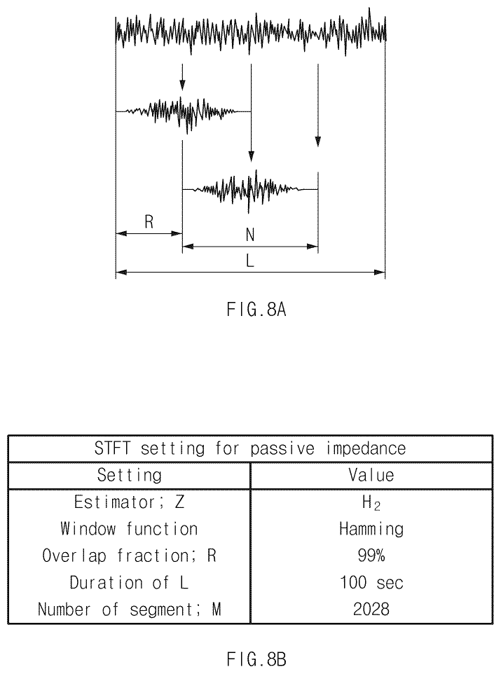

FIG. 8A and FIG. 8B illustrate an example of STFT settings. FIG. 8A and FIG. 8B show an example in which the segment is set to 300 and the overlap is set to 1. FIG. 8A shows a diagram for describing factors R, L, and N in a signal, and FIG. 8B shows an example of STFT settings.

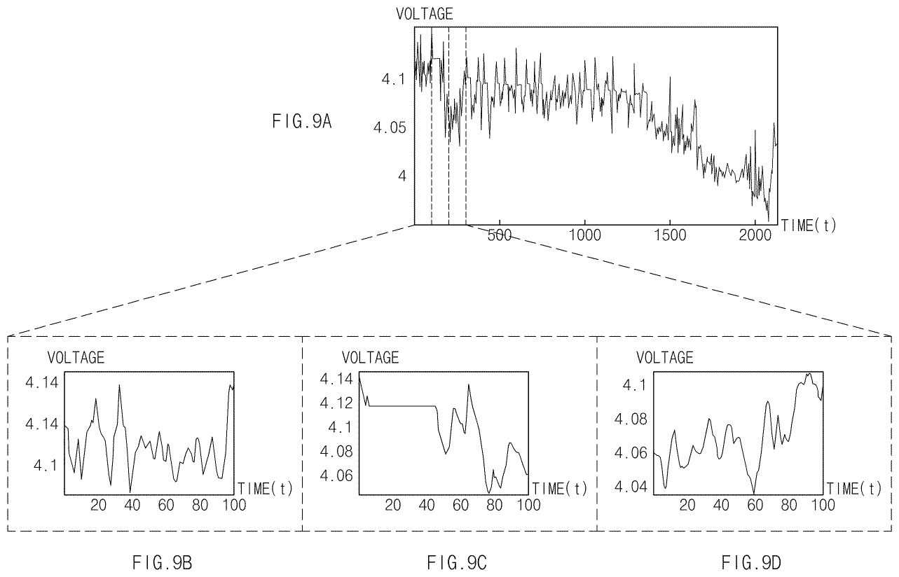

FIG. 9A to FIG. 9D illustrate an example of segment and overlap settings during a STFT. FIG. 9A to FIG. 9D show an example in which the segment is set to 300 and the overlap is set to 1.

The battery state diagnosis apparatus 100 may be configured to perform Fourier transform on the voltage and current signals for each segment.

FIG. 9A indicates a voltage signal that performed the DWT, FIG. 9B indicates a voltage signal corresponding to segment 0-300s in FIG. 9A, FIG. 9C indicates a voltage signal corresponding to segment 1-301s in FIG. 9A, and FIG. 9D indicates a voltage signal corresponding to 2-302s. In this way, the frequency component of each segment may be extracted by extracting 300 segments and setting the overlap by 1.

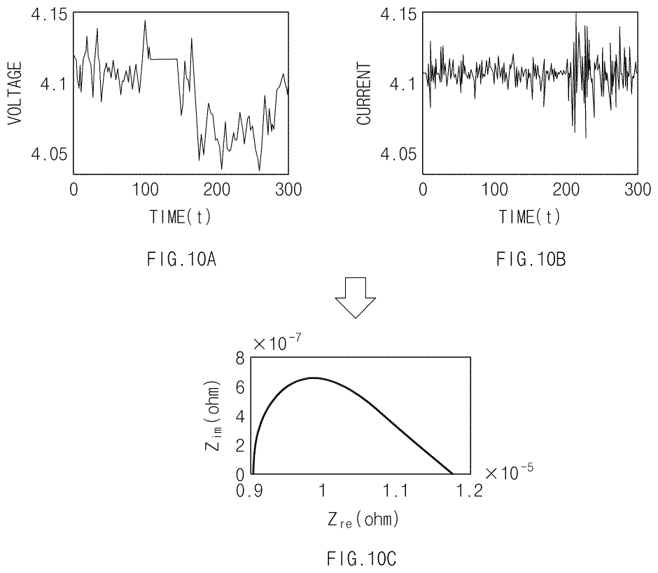

FIG. 10A to 10C illustrate a view for describing an example impedance extraction process based on a STFT.

FIG. 10A indicates a voltage signal of segment 0-300s, and FIG. 10B indicates a current signal of segment 0-300s. After extracting frequency characteristics for the voltage signal of segment 0-300s and the current signal of segment 0-300s using following Equation 7, the frequency characteristics are sequentially extracted for the voltage and current signals of the next segment 1-301s, and after extracting all the extracted frequency characteristics, the voltage frequency characteristics and the current frequency characteristics are applied to Ohm's law of the above Equation 6 to extract impedance. FIG. 10C shows the extracted impedance.

$${F}_{v , i} ( τ , ω ) = {\int }_{- ∞}^{∞} f ( t ) w ( t - τ ) {e}^{- j ω ( t - τ )} d t \qquad Equation 7$$

Herein, Fv, i indicates frequency characteristics of voltage and current, f(t) indicates a time series function, and t−τ indicates a window function.

In this way, according to the present disclosure, by performing a STFT, the time series-based voltage and current signals processed by DWT may be converted into frequency-based voltage and current signals, and the impedance may be extracted using these frequency-based voltage and current signals.

For example, in response to a case where the segment is 300, the impedance may be extracted by performing the STFT on the segment 0-300s of the DWT processed voltage and current signals, by moving the overlap by “1” and performing all STFTs for each segment, and by extracting the frequency-based current and voltage signals for each segment.

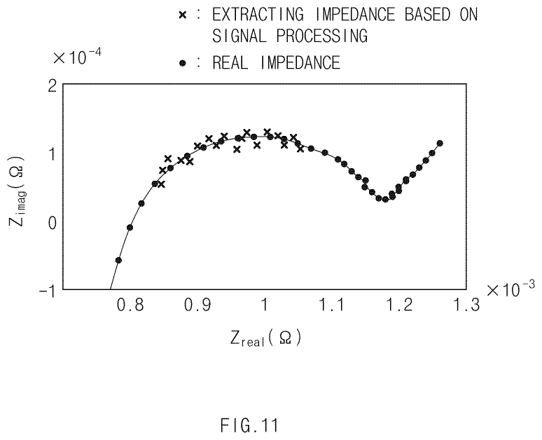

FIG. 11 illustrates an example of comparing results of battery impedance extraction based on signal processing and results of battery impedance extraction using EIS equipment.

Referring to FIG. 11, it may be seen that a result of battery impedance extraction based on signal processing according to an exemplary embodiment of the present disclosure is almost similar to a result of battery impedance extraction using EIS equipment.

In this way, according to the present disclosure, space and cost consumption for EIS equipment may be prevented by accurately extracting battery impedance using a signal processing technique without EIS equipment.

Furthermore, according to the present disclosure, safety of electric vehicles may be improved by accurately diagnosing the battery state using battery impedance extracted based on signal processing.

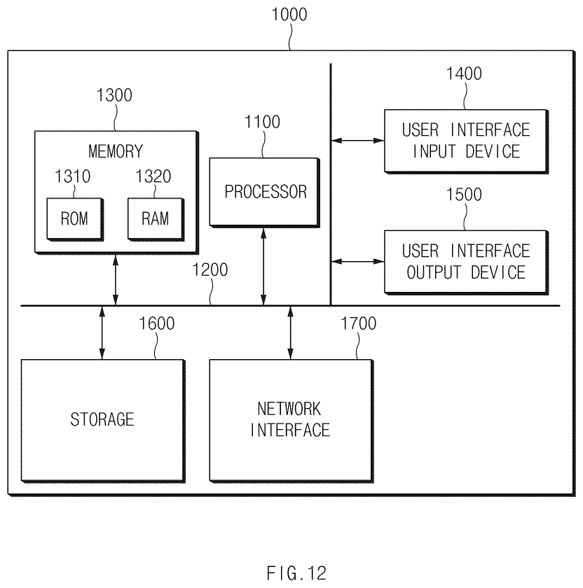

FIG. 12 illustrates an example computing system.

Referring to FIG. 12, the computing system 1000 includes at least one processor 1100 connected through a bus 1200, a memory 1300, a user interface input device 1400, a user interface output device 1500, and a storage 1600, and a network interface 1700.

The processor 1100 may be a central processing unit (CPU) or a semiconductor device that performs processing on commands stored in the memory 1300 and/or the storage 1600. The memory 1300 and the storage 1600 may include various types of volatile or nonvolatile storage media. For example, the memory 1300 may include a read only memory (ROM) 1310 and a random access memory (RAM) 1320.

Accordingly, steps of a method or algorithm described in connection with the exemplary embodiments included herein may be directly implemented by hardware, a software module, or a combination of the two, executed by the processor 1100. The software module may reside in a storage medium (i.e., the memory 1300 and/or the storage 1600) such as a RAM memory, a flash memory, a ROM memory, an EPROM memory, an EEPROM memory, a register, a hard disk, a removable disk, and a CD-ROM.

An exemplary storage medium is coupled to the processor 1100, which can read information from and write information to the storage medium. Alternatively, the storage medium may be integrated with the processor 1100. The processor and the storage medium may reside within an application specific integrated circuit (ASIC). The ASIC may reside within a user terminal. Alternatively, the processor and the storage medium may reside as separate components within the user terminal.

The above description is merely illustrative of the technical idea of the present disclosure, and those skilled in the art to which the present disclosure pertains may make various modifications and variations without departing from the essential characteristics of the present disclosure.

Therefore, the exemplary embodiments disclosed in the present disclosure are not intended to limit the technical ideas of the present disclosure, but to explain them, and the scope of the technical ideas of the present disclosure is not limited by these exemplary embodiments. The protection range of the present disclosure should be interpreted by the claims below, and all technical ideas within the equivalent range should be interpreted as being included in the scope of the present disclosure.

1. A battery state diagnosis apparatus comprising:
a processor configured to extract battery impedance by:
obtaining voltage and current signals outputted from a battery management system of an electric vehicle;
removing noise by performing first signal processing on the voltage and current signals outputted from the battery management system; and
extracting a frequency characteristic by performing second signal processing on the voltage and current signals from which the noise has been removed; and
a storage configured to store data and algorithms driven by the processor.

2. The battery state diagnosis apparatus of claim 1, wherein the first signal processing includes a discrete wavelet transform (DWT).

3. The battery state diagnosis apparatus of claim 1, wherein the second signal processing includes a short-time Fourier Transform (STFT).

4. The battery state diagnosis apparatus of claim 2, wherein the processor is further configured, during the first signal processing, to decompose each of the voltage and current signals outputted from the battery management system into a high-frequency component and a low-frequency component according to at least one decomposition level (n).

5. The battery state diagnosis apparatus of claim 4, wherein the processor is further configured to derive a decomposition coefficient by taking convolution of each of the voltage and the current signals outputted from the battery management system and a wavelet function.

6. The battery state diagnosis apparatus of claim 4, wherein the processor is further configured to derive an approximation coefficient by taking convolution of the low-frequency component with a scaling function for low-frequency convolution, and to derive a detailed coefficient by taking convolution of the low-frequency component with a wavelet function for high-frequency convolution.

7. The battery state diagnosis apparatus of claim 6, wherein the processor is further configured to derive a decomposition coefficient including the detailed coefficient and the approximate coefficient.

8. The battery state diagnosis apparatus of claim 5, wherein the processor is further configured to remove noise by determining whether the decomposition coefficient is equal to or smaller than a predetermined threshold.

9. The battery state diagnosis apparatus of claim 3, wherein the processor is further configured to convert time-series-based voltage and current signals from which noise has been removed by performing the first signal processing into frequency-based voltage and current signals by performing the second signal processing.

10. The battery state diagnosis apparatus of claim 9, wherein the processor is further configured to extract frequency-based voltage and current signals by dividing the time-series-based voltage and current signals from which noise has been removed by performing the first signal processing into a plurality of segments based on time series and performing the second signal processing.

11. The battery state diagnosis apparatus of claim 10, wherein the processor is further configured to perform the second signal processing for each of the segments by applying a predetermined overlap.

12. The battery state diagnosis apparatus of claim 10, wherein the processor is further configured to extract the battery impedance by applying Ohm's law to the frequency-based voltage and current signals.

13. The battery state diagnosis apparatus of claim 12, wherein the processor is further configured to separate and extract imaginary and real parts of the battery impedance.

14. The battery state diagnosis apparatus of claim 1, wherein the processor is further configured to diagnose a battery state using the battery impedance.

15. A battery state diagnosis method comprising:
obtaining, by a processor, voltage and current signals outputted from a battery management system of an electric vehicle;
removing, by the processor, noise by performing first signal processing on the voltage and current signals outputted from the battery management system;
extracting, by the processor, a frequency characteristic by performing second signal processing on the voltage and current signals from which the noise has been removed; and
extracting, by the processor, battery impedance using the frequency characteristic.

16. The battery state diagnosis method of claim 15, wherein the first signal processing includes a discrete wavelet transform (DWT), and the second signal processing includes a short-time Fourier Transform (STFT).

17. The battery state diagnosis method of claim 15, wherein removing the noise by performing the first signal processing includes:
decomposing, by the processor, each of the voltage and current signals outputted from the battery management system into a high-frequency component and a low-frequency component according to at least one decomposition level (n);
deriving, by the processor, a decomposition coefficient by taking convolution of each of the voltage and the current signals outputted from the battery management system and a wavelet function; and
removing, by the processor, noise by determining whether the decomposition coefficient is equal to or smaller than a predetermined threshold.

18. The battery state diagnosis method of claim 15, wherein extracting the frequency characteristic by performing the second signal processing includes converting, by the processor, time-series-based voltage and current signals from which noise has been removed by performing the first signal processing into frequency-based voltage and current signals by performing the second signal processing.

19. The battery state diagnosis method of claim 18, wherein extracting the frequency characteristic by performing the second signal processing includes extracting, by the processor, frequency-based voltage and current signals by dividing the time-series-based voltage and current signals from which noise has been removed by performing the first signal processing into a plurality of segments based on time series and performing the second signal processing.

20. The battery state diagnosis method of claim 19, wherein extracting the frequency characteristic by performing the second signal processing includes:
performing, by the processor, the second signal processing for each of the segments by applying a predetermined overlap; and
extracting, by the processor, the battery impedance by applying Ohm's law to the frequency-based voltage and current signals.
